(19) United States
(12) Patent Application Publication
(10) Pub. No.: US 2007/0295488 A1
(43) Pub. Date: Dec. 27, 2007

(54) Thermosyphon for operation in multiple orientations relative to gravity

(76) Inventors: Louis C. Fielding, Portland, OR (US); Mark A. Trautman, Aloha, OR (US); Paul J. Gwin, Orangevale, CA (US)

Correspondence Address: Buckley, Maschoff & Talwalkar LLC;Attorney for INTEL Corporation, Five Elm Street, New Canaan, CT, 06840, US

(21) Appl. No.: 11/475,350

(22) Filed: Jun. 27, 2006

(51) Int. Cl. H05K 7/20

(52) U.S. Cl. 165/104.33; 361/700; 29/890.032

(57) ABSTRACT

Some aspects provide a chamber to hold a fluid, the chamber including an evaporation surface and a condensation wall having a condensation surface, and a heat dissipator coupled to the condensation wall. The evaporation surface is to evaporate the fluid and the condensation surface is to condense the evaporated fluid in a case that the apparatus is in a first orientation and in a case that the apparatus is in a second orientation that is rotated substantially ninety degrees from the first orientation around an axis that does not intersect the evaporation surface. In some aspects, the evaporation surface comprises structures to facilitate boiling nucleation.

### BACKGROUND

Electrical devices, such as computers, are comprised of multiple electrical components (e.g., processors, voltage regulators, and/or memory devices). Electrical components typically dissipate unused electrical energy as heat, which may damage the electrical components and/or their surroundings (e.g., other electrical components and/or structural devices such as casings, housings, and/or electrical interconnects). Various systems are utilized to remove heat from electrical components and their surroundings.

Some systems use a metallic mass (e.g., a heat sink) to absorb heat and a fan to cool the mass. Other systems may incorporate a cooling fluid. For example, heat pipes and vapor chambers contain a small amount of fluid which evaporates due to absorbed heat, condenses, and returns to an evaporation surface through a wick structure via capillary action. If the demand for heat dissipation exceeds a critical level, such capillary action cannot return the fluid to the evaporation surface at a required rate.

A thermosyphon also uses fluid to absorb and dissipate heat. In operation, the fluid evaporates from an evaporation surface and condenses on a condensation surface, where the thusly-transported heat can be dissipated into air-cooled fins or the like. The condensed fluid flows back to the evaporation surface and the cycle then repeats. Thermosyphon operation is therefore dependent on the orientation of the thermosyphon relative to an existing gravitational force. Accordingly, the application, efficiency, and usefulness of conventional thermosyphons may be limited.

### BRIEF DESCRIPTION OF THE DRAWINGS

FIGS. 1A and 1B comprise block diagrams of a system in two different orientations according to some embodiments.

FIGS. 2A and 2B comprise perspective views of an apparatus in two different orientations according to some embodiments

FIGS. 3A and 3B comprise perspective views of an apparatus according to some embodiments.

FIGS. 4A and 4B comprise perspective views of an apparatus according to some embodiments.

FIG. 5 is a perspective view of an apparatus according to some embodiments.

FIG. 6 is a perspective view of an apparatus according to some embodiments.

FIG. 7 is a perspective view of an apparatus according to some embodiments.

FIG. 8 is a flow diagram of a process to fabricate an apparatus according to some embodiments.

FIG. 9A through 9D illustrate fabrication of an apparatus according to some embodiments.

FIG. 10 is a block diagram of a system according to some embodiments.

### DETAILED DESCRIPTION

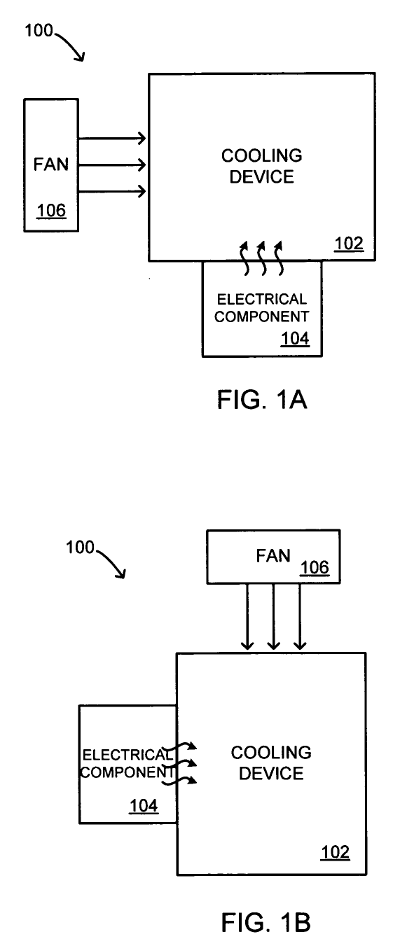

FIG. 1A is a block diagram of system 100 according to some embodiments. System 100 may, according to some embodiments, comprise elements of a computing system and/or other electrical device. System 100 includes cooling device 102, electrical component 104 and fan 106. The various systems described herein are depicted for use in explanation, but not limitation, of described embodiments. Different types, layouts, quantities, and configurations of any of the systems described herein may be used without deviating from the scope of some embodiments.

Cooling device 102 may operate to receive heat from electrical component 104 and to dissipate the heat with the assistance of fan 106. For example, electrical component 104 may generate heat (e.g., represented by wavy directional lines) that is conducted through surfaces of cooling device 102 which may, for example, be coupled, attached, and/or adjacent to electrical component 104. These surfaces may, for example, be physically and/or thermally coupled to receive heat from the electrical component 104. Some embodiments may omit fan 106 and/or substitute another device for fan 106.

More particularly, cooling device 102 may comprise a chamber to hold a fluid. The chamber may include an evaporation surface and a condensation wall having a condensation surface. Cooling device 102 may also include a heat dissipator coupled to the condensation wall. In operation, the evaporation surface is to evaporate the fluid and the condensation surface is to condense the evaporated fluid in a case that cooling device 100 is in the first orientation shown in FIG. 1A.

In some embodiments, the evaporation surface includes structures to facilitate boiling nucleation. The evaporation surface may be a portion of an evaporation wall to which electrical component 104 is coupled. Accordingly, heat generated from electrical component 104 may be transferred to fluid located on the evaporation surface, carried to the condensation surface by thusly-evaporated fluid, and transferred to the heat dissipator via the condensation wall. Fan 106 may then facilitate cooling of the heat dissipator.

FIG. 1B illustrates some embodiments of system 100 in a second orientation. Assuming that the evaporation surface is located at the coupling of cooling device 102 and electrical component 104, FIG. 1B reflects rotation of system 100 of FIG. 1A substantially ninety degrees around an axis that does not intersect the evaporation surface. The evaporation surface is to evaporate the fluid and the condensation surface is to condense the evaporated fluid in a case that cooling device 102 is in the second orientation shown in FIG. 1B.

According to some embodiments, FIG. 1A illustrates system 100 in a “desktop” orientation and FIG. 1B illustrates system 100 in a “tower” orientation. In a case that system 100 is an element of a mobile device, FIGS. 1A and 1B may reflect other orientations that may be anticipated during use of the mobile device.

Electrical component 104 may, for example, be any type or configuration of electrical components that are or become known. In some embodiments, electrical component 102 may comprise one or more processors, Voltage Regulator Module (VRM) devices, memory devices, and/or other electrical components.

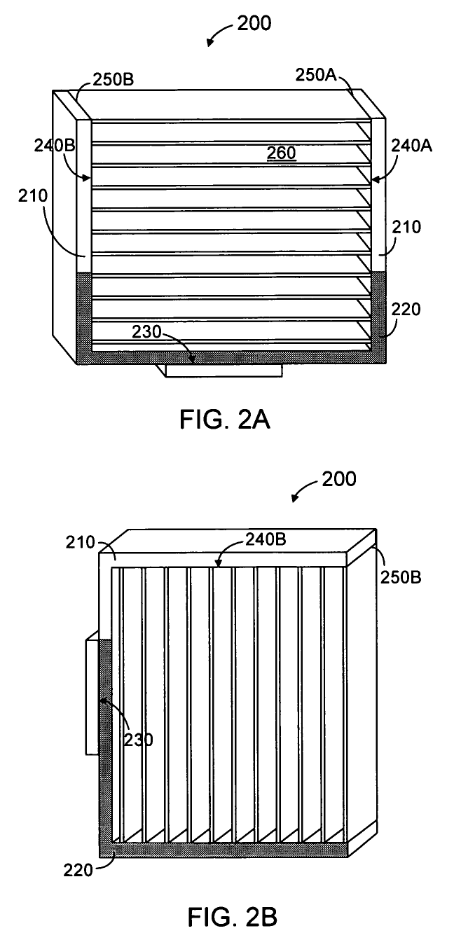

FIGS. 2A and 2B comprise perspective views of cooling device 200 according to some embodiments. In some embodiments, cooling device 200 may share characteristics of cooling device 100 of FIG. 1. Cooling device 200 may be composed of any suitable combination of materials that is or becomes known.

Cooling device 200 includes chamber 210 to hold fluid 220. Fluid 220 may comprise water or another suitable fluid. Chamber 210 includes evaporation surface 230 and condensation surfaces 240. Condensation surfaces 240 are elements of condensation walls 250, to which a plurality of fins 260 are coupled. Evaporation surface 230 is to evaporate fluid 220 and condensation surfaces 240 are to condense the evaporated fluid. Gravitational forces then cause the condensate to return to evaporation surface 230 as illustrated in FIG. 2A. Cooling device 200 may thereby cool any component thermally coupled to evaporation surface 230.

FIG. 2B illustrates rotation of cooling device 200 substantially ninety degrees around an axis that does not intersect evaporation surface 230. In some embodiments, condensation walls 250 are vertical in the orientation illustrated in FIG. 2A. Accordingly, condensation walls 250 may be considered horizontal as illustrated in FIG. 2B. Embodiments and usage of cooling device 200 are not limited to vertical and horizontal orientations.

Cooling device 200 as oriented in FIG. 2B may operate as described above with respect to FIG. 2A. Specifically, fluid 220 contacts evaporation surface 230. Moreover, evaporated fluid 220 travels from evaporation surface 230 and condenses on condensation surface 240B. Thermal energy that is thereby carried to condensation wall 250B is then transferred to fins 260. Next, gravitational forces cause the condensate to return to evaporation surface 230 as illustrated in FIG. 2B.

Fins 260 may dissipate the transferred thermal energy to the surrounding air. A fan such as fan 106 may facilitate this dissipation. Some embodiments may also or alternatively include fins coupled to an outside wall of chamber 210.

Cooling device 200 as shown in FIG. 2B may be angled slightly to facilitate the above-described return of the condensate to evaporation surface 230. In this regard, the orientation of cooling device 200 in FIG. 2A may be slightly skew of vertical such that a ninety degree rotation of cooling device 200 results in an orientation that is slightly skew of horizontal.

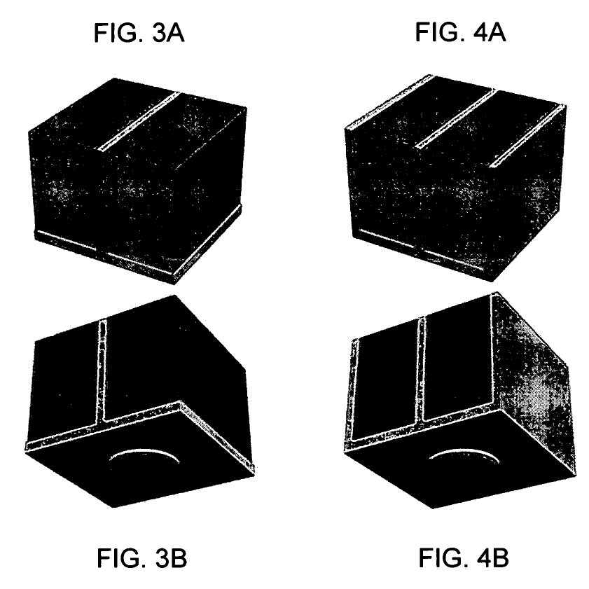

FIG. 3A through FIG. 7 comprise perspective views of apparatuses according to some embodiments. The illustrated apparatuses may be composed of any suitable materials and may be fabricated using any currently- or hereafter-known techniques. Each apparatus includes a chamber to hold a fluid and that includes an evaporation surface and a condensation wall having a condensation surface, and a heat dissipator coupled to the condensation wall. The evaporation surface is to evaporate the fluid and the condensation surface is to condense the evaporated fluid in a case that the apparatus is in a first orientation and in a case that the apparatus is in a second orientation that is rotated substantially ninety degrees from the first orientation around an axis that does not intersect the evaporation surface.

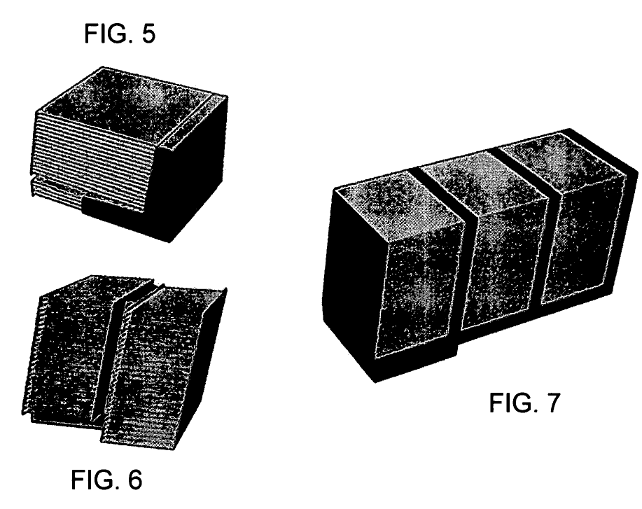

More specifically, FIGS. 3A and 3B illustrate a “T”-shaped chamber, where the base of the “T” may promote additional heat spreading. FIGS. 4A and 4B, on the other hand, illustrate a cooling device having a “W”-shaped chamber. FIGS. 5 and 6 illustrate “L”-shaped chambers, while FIG. 7 illustrates an “F”-shaped chamber. Some embodiments of the FIG. 5 through FIG. 7 cooling devices may operate only if rotated clockwise (as opposed to either direction), but may provide additional volume available for air-side heat dissipators. Moreover, some embodiments of the FIG. 5 through FIG. 7 cooling devices will not be physically centered over an electrical component to which they are mounted.

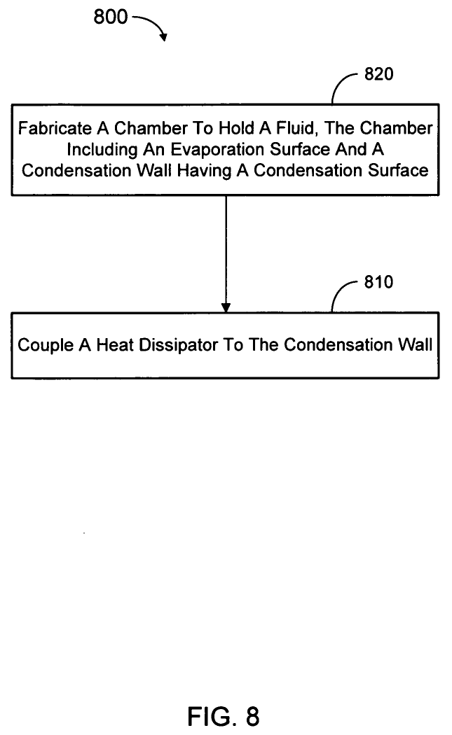

FIG. 8 is a flow diagram of process 800 according to some embodiments. Process 800 may be executed by any combination of hardware, software or manual systems. Process 800 may, in some embodiments, be performed by an original equipment manufacturer that purchases an electrical component (e.g., a microprocessor) and builds a computing platform using the component.

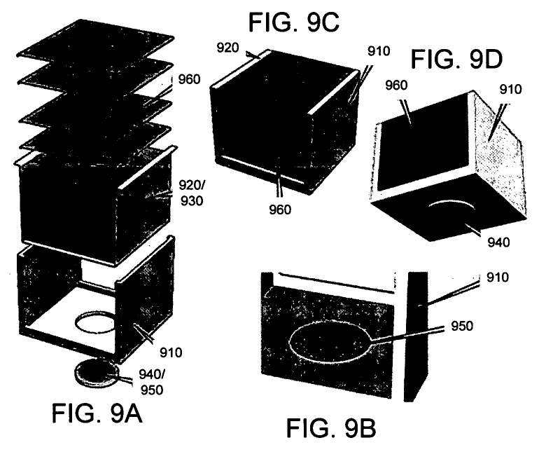

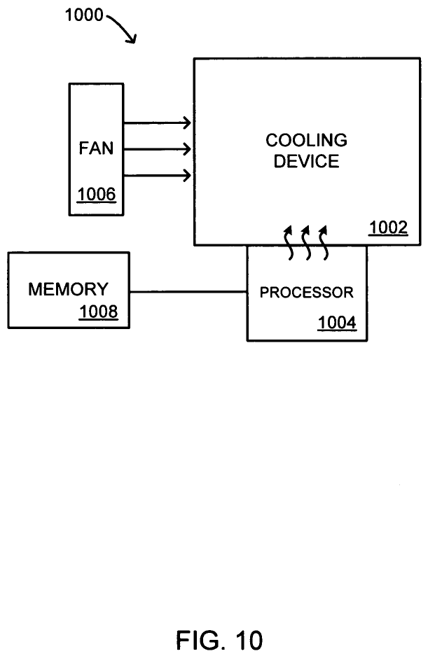

Initially, at 810, a chamber to hold a fluid is fabricated. The chamber includes an evaporation surface and a condensation wall which itself includes a condensation surface. FIG. 9A illustrates fabrication of cooling device 900 according to some embodiments of 810. Specifically, FIG. 9A illustrates fabrication of a chamber using housing 910, conductive sheet 920 and evaporator slug 940.

In some embodiments, housing 910 comprises cast aluminum and sheet 920 comprises a copper sheet. Using the terminology presented herein, sheet 920 comprises a condensation wall including condensation surface 930. Sheet 920 may be brazed or laminated to housing 910 according to some embodiments.

Evaporator slug 940 may be brazed to housing 910. A lower surface of slug 940 may be intended to contact an electrical component, while an upper surface of slug 940 comprises structures 950 to facilitate boiling nucleation. Structures 950 are shown in greater detail in FIG. 9B, and may effect low thermal resistance through nucleate boiling by creating many vapor nucleation sites. According to some embodiments, structures 950 support dormant nucleation sites (or vapor bubbles). Structures 950 may include, but are not limited to, spray-on microporous coatings, sintered copper coatings, fin arrays, screens, and pore and cavity structures.

Some embodiments do not include slug 940. Instead, a bottom surface of housing 910 is solid and operates as an evaporator surface as described above. This evaporator surface may include structures to facilitate boiling nucleation according to some embodiments.

Returning to process 800, a heat dissipator is coupled to the condensation wall at 820. Any type of heat dissipator that is or becomes known may be employed at 820. FIG. 9A illustrates the coupling of fins 960 to condensation wall 920 of device 900. According to some embodiments, fins 960 are composed of one or more of aluminum, copper and Beryllium. FIGS. 9C and 9D illustrate perspective views of cooling device 900 after completion of process 800.

Referring now to FIG. 10, a block diagram of system 1000 according to some embodiments is shown. In some embodiments, system 1000 may be similar to system 100 and cooling device 1002 may be similar to any of cooling devices 102, 200, 900 and/or those illustrated in FIGS. 3 through 7.

Processor 1004 may be or include any number of processors, which may be or include any type or configuration of processor, microprocessor, and/or micro-engine that is or becomes known or available. Memory 1008 may be or include, according to some embodiments, one or more magnetic storage devices, such as hard disks, one or more optical storage devices, and/or solid state storage. Memory 1008 may store, for example, applications, programs, procedures, and/or modules that store instructions to be executed by processor 1004. Memory 1008 may comprise, according to some embodiments, any type of memory for storing data, such as a Single Data Rate Random Access Memory (SDR-RAM), a Double Data Rate Random Access Memory (DDR-RAM), or a Programmable Read Only Memory (PROM).

The several embodiments described herein are solely for the purpose of illustration. The various features described herein need not all be used together, and any one or more of those features may be incorporated in a single embodiment. Some embodiments may include any currently or hereafter-known versions of the elements described herein. Therefore, persons skilled in the art will recognize from this description that other embodiments may be practiced with various modifications and alterations.

What is claimed is:

1. An apparatus, comprising:
a chamber to hold a fluid, the chamber including an evaporation surface and a condensation wall having a condensation surface; and
a heat dissipator coupled to the condensation wall,
wherein the evaporation surface is to evaporate the fluid and the condensation surface is to condense the evaporated fluid in a case that the apparatus is in a first orientation and in a case that the apparatus is in a second orientation that is rotated substantially ninety degrees from the first orientation around an axis that does not intersect the evaporation surface.

2. An apparatus according to claim 1, wherein the evaporation surface comprises structures to facilitate boiling nucleation.

3. An apparatus according to claim 1, further comprising:
a plurality of heat dissipators coupled to the condensation wall.

4. An apparatus according to claim 1, wherein the condensation wall is slightly skew of vertical in a case that the apparatus is in the first orientation, and
wherein the condensation wall is slightly skew of horizontal in a case that the apparatus is in the second orientation.

5. An apparatus according to claim 1, wherein the chamber further comprises:
a second condensation wall having a second condensation surface to condense the evaporated fluid in a case that the apparatus is in at least one of the first orientation and the second orientation.

6. An apparatus according to claim 5, wherein the heat dissipator is coupled to the second condensation wall.

7. An apparatus according to claim 1, wherein the evaporated fluid condensed on the condensation surface is to return to the evaporation surface due substantially to gravitational forces in a case that the apparatus is in the first orientation and in the second orientation.

8. A method, comprising:
fabricating a chamber to hold a fluid, the chamber including an evaporation surface and a condensation wall having a condensation surface; and
coupling a heat dissipator to the condensation wall,
wherein the evaporation surface is to evaporate the fluid and the condensation surface is to condense the evaporated fluid in a case that the apparatus is in a first orientation and in a case that the apparatus is in a second orientation that is rotated substantially ninety degrees from the first orientation around an axis that does not intersect the evaporation surface.

9. A method according to claim 1, wherein the evaporation surface comprises structures to facilitate boiling nucleation.

10. A method according to claim 1, further comprising:
coupling a plurality of heat dissipators to the condensation wall.

11. A method according to claim 1, wherein the condensation wall is slightly skew of vertical in a case that the apparatus is in the first orientation, and
wherein the condensation wall is slightly skew of horizontal in a case that the apparatus is in the second orientation.

12. A method according to claim 1, wherein the chamber further comprises:
a second condensation wall having a second condensation surface to condense the evaporated fluid in a case that the apparatus is in at least one of the first orientation and the second orientation.

13. A method according to claim 12, further comprising:
coupling the heat dissipator to the second condensation wall.

14. A system, comprising:
a chamber to hold a fluid, the chamber including an evaporation wall having an evaporation surface, and a condensation wall having a condensation surface;
a heat dissipator coupled to the condensation wall;
a processor coupled to the evaporation wall; and
a double data rate memory coupled to the processor, wherein the memory is to store instructions to be executed by the processor,
wherein the evaporation surface is to evaporate the fluid and the condensation surface is to condense the evaporated fluid in a case that the apparatus is in a first orientation and in a case that the apparatus is in a second orientation that is rotated substantially ninety degrees from the first orientation around an axis that does not intersect the evaporation surface.

15. A system according to claim 14, wherein the evaporation surface comprises structures to facilitate boiling nucleation.

16. A system according to claim 14, further comprising:
a plurality of heat dissipators coupled to the condensation wall.

17. A system according to claim 14, wherein the condensation wall is slightly skew of vertical in a case that the apparatus is in the first orientation, and
wherein the condensation wall is slightly skew of horizontal in a case that the apparatus is in the second orientation.

18. A system according to claim 14, wherein the chamber further comprises:
a second condensation wall having a second condensation surface to condense the evaporated fluid in a case that the apparatus is in at least one of the first orientation and the second orientation.

19. A system according to claim 18, wherein the heat dissipator is coupled to the second condensation wall.

20. A system according to claim 14, wherein the evaporated fluid condensed on the condensation surface is to return to the evaporation surface due substantially to gravitational forces in a case that the apparatus is in the first orientation and in the second orientation.
